(19) United States
(12) Patent Application Publication
(10) Pub. No.: US 2017/0167022 A1
(43) Pub. Date: Jun. 15, 2017

(54) APPARATUS FOR HIGH SPEED ATOMIC LAYER DEPOSITION AND DEPOSITION METHOD USING THE SAME

(71) Applicant: LG Chem, Ltd., Seoul (KR)

(72) Inventor: Hangbeum Shin, Daejeon (KR)

(73) Assignee: LG Chem, Ltd., Seoul (KR)

(21) Appl. No.: 14/966,077

(22) Filed: Dec. 11, 2015

(51) Int. Cl. C23C 16/455; H01L 29/06; H01L 21/02

(52) U.S. Cl. CPC C23C 16/45561; H01L 21/0262; H01L 29/0657; C23C 16/45544

(57) ABSTRACT

Disclosed herein is an atomic layer deposition apparatus including a reaction chamber provided with a chamber inlet, through which an inert gas or a precursor gas, which is a mixture of the inert gas and a gas-phase precursor, is introduced into the reaction chamber, and a chamber outlet, through which gas is discharged from the reaction chamber, a gas supply device provided with a gas supply pipe, along which an inert gas is supplied, a precursor storage having a precursor for generating a precursor gas to be supplied to the reaction chamber received therein, the precursor storage being provided with an inlet, through which the inert gas supplied along the gas supply pipe is introduced into the precursor storage, and an outlet, through which the precursor gas is discharged from the precursor storage, a first storage connected to the chamber inlet for temporarily storing an inert gas or a precursor gas to be supplied into the reaction chamber, a first valve located at an outlet of the first storage for controlling the supply of the inert gas or the precursor gas from the first storage into the reaction chamber, a second valve located at an inlet of the first storage for controlling the supply of the inert gas or the precursor gas into the first storage, a third valve connected to the outlet of the precursor storage and to the second valve via a gas conduit, a bypass conduit having one end connected to the gas supply pipe and the other end connected to the gas conduit between the second valve and the third valve, a second storage located on the bypass conduit for temporarily storing an inert gas, a fourth valve located at an outlet of the second storage for controlling the supply of an inert gas from the second storage to the gas conduit between the second valve and the third valve, a fifth valve located at an inlet of the second storage for controlling the supply of an inert gas from the gas supply pipe into the second storage, and a vacuum pump connected to the chamber outlet of the reaction chamber for discharging an unreacted gas and a reaction by-product that remain in the reaction chamber and the gas conduit from the atomic layer deposition apparatus.

### TECHNICAL FIELD

The present invention relates to an apparatus for high speed atomic layer deposition and a deposition method using the same.

### BACKGROUND ART

Recent consumers' demand has increased the necessity for developing electronic devices that are capable of performing various functions and small-sized portable devices. As a result, the importance of developing technology that is capable of intensively performing various functions on a semiconductor device has also increased.

In order to manufacture a thin film that is used for the semiconductor device such that the thin film has a more precise and complicated structure, it is necessary to control the shape of the thin film in atomic unit. In addition, it is necessary for the thin film to be manufactured at a low deposition temperature such that the thin film exhibits excellent step covering and such that diffusion and oxidation are prevented from occurring on the interface.

In chemical vapor deposition (CVD), which has been mainly used as a thin film deposition method, an external energy, such as heat, an electric field, or light, is used to evaporate a raw material and to deposit the evaporated raw material on a base material. For this reason, it is difficult to accurately control the thickness of the thin film. Furthermore, deposition is performed in a high-temperature environment, whereby the thin film may be easily denaturalized. As a result, it is difficult to satisfy the above-mentioned requirements.

In recent years, atomic layer deposition that is capable of depositing a thin film in atomic layer unit has been highlighted as an alternative to the chemical vapor deposition.

In the atomic layer deposition, deposition is performed at a relatively low temperature, and a thin film is deposited in single atomic layer unit, unlike the chemical vapor deposition, in which a thin film is deposited through vapor reaction. As a result, it is possible to accurately manufacture a nano-level thin film such that the thin film has a desired thickness. In a case in which the thin film is manufactured using atomic layer deposition, the content of impurities is low, and uniformity of the thin film is high.

In the atomic layer deposition, however, a deposition speed is low. That is, in a deposition process using a conventional atomic layer deposition method, it is necessary to strictly separate reaction materials from each other during the deposition process. In addition, a thin film growth speed is low, with the result that it takes a plenty of time to perform the deposition process.

For example, on the assumption that one deposition process is performed for one second in order to deposit a film having 1 angstrom, it may take a total of about 3 hours to deposit a film having 1 micrometer. That is, a large number of deposition process cycles may be carried out depending upon the target thickness of a thin film to be manufactured. For this reason, it is very important to reduce the time necessary to perform the deposition process cycles in order to improve production efficiency. In particular, it is necessary to reduce time during which a precursor is supplied into a reaction chamber and to reduce time necessary to perform a purge process.

FIG. 1 is a schematic view showing a conventional atomic layer deposition apparatus 10. As shown in FIG. 1, the atomic layer deposition apparatus 10 includes a pair of mass flow controllers 4 and 5 for accurately controlling the supply of an inert gas from an inert gas supply device 2 in order to supply an inert gas or a precursor 6 into a reaction chamber 1. However, a discharge flow rate per unit time of the mass flow controllers 4 and 5 is very low, with the result that time necessary to supply the precursor 6 and time necessary to purge the reaction chamber 1, which constitute a large part of the deposition process cycle, are greatly increased.

Meanwhile, a method of simultaneously depositing a large number of base materials using a semi-batch type reaction chamber has been developed in order to reduce process time of the atomic layer deposition, with the result that it is possible to increase a speed at which a thin film is deposited.

Even in a case in which the semi-batch type reaction chamber is used, however, process conditions may be excessively changed depending upon the position on which a substrate is placed, whereby it may be difficult to acquire a thin film having uniform quality. As a result, a product defect rate may be increased, or it may be difficult to produce a thin film having high quality.

Therefore, there is a high necessity for technology that is capable of fundamentally solving the above problems.

### DISCLOSURE

### Technical Problem

Therefore, the present invention has been made to solve the above problems, and other technical problems that have yet to be resolved.

As a result of a variety of extensive and intensive studies and experiments to solve the problems as described above, the inventors of the present application have found that, in a case in which an atomic layer deposition apparatus is configured to include a first storage and a second storage for temporarily storing an inert gas or a precursor gas to be supplied into a reaction chamber, in place of mass flow controllers, it is possible to reduce time necessary to supply a precursor gas into the reaction chamber and to reduce time necessary to discharge an unreacted gas and a reaction by-product that remain in the atomic layer deposition apparatus from the atomic layer deposition apparatus, and, in addition, it is possible to remove a precursor gas and a reaction by-product that remain in the reaction chamber and a precursor gas supply line extending from an outlet of a precursor storage to a chamber inlet of the reaction chamber from the atomic layer deposition apparatus with high removal efficiency, whereby it is possible to manufacture a thin film having high-purity quality. The present invention has been completed based on these findings.

### Technical Solution

In accordance with one aspect of the present invention, the above and other objects can be accomplished by the provision of an atomic layer deposition apparatus including a reaction chamber provided with a chamber inlet, through which an inert gas or a precursor gas, which is a mixture of the inert gas and a gas-phase precursor, is introduced into the reaction chamber, and a chamber outlet, through which gas is discharged from the reaction chamber, a gas supply device provided with a gas supply pipe, along which an inert gas is supplied, a precursor storage having a precursor for generating a precursor gas to be supplied to the reaction chamber received therein, the precursor storage being provided with an inlet, through which the inert gas supplied along the gas supply pipe is introduced into the precursor storage, and an outlet, through which the precursor gas is discharged from the precursor storage, a first storage connected to the chamber inlet for temporarily storing an inert gas or a precursor gas to be supplied into the reaction chamber, a first valve located at an outlet of the first storage for controlling the supply of the inert gas or the precursor gas from the first storage into the reaction chamber, a second valve located at an inlet of the first storage for controlling the supply of the inert gas or the precursor gas into the first storage, a third valve connected to the outlet of the precursor storage and to the second valve via a gas conduit, a bypass conduit having one end connected to the gas supply pipe and the other end connected to the gas conduit between the second valve and the third valve, a second storage located on the bypass conduit for temporarily storing an inert gas, a fourth valve located at an outlet of the second storage for controlling the supply of an inert gas from the second storage to the gas conduit between the second valve and the third valve, a fifth valve located at an inlet of the second storage for controlling the supply of an inert gas from the gas supply pipe into the second storage, and a vacuum pump connected to the chamber outlet of the reaction chamber for discharging an unreacted gas and a reaction by-product that remain in the reaction chamber and the gas conduit from the atomic layer deposition apparatus.

The first storage may temporarily store a precursor gas at a predetermined pressure, and the precursor gas from the first storage may be rapidly supplied into the reaction chamber such that the precursor gas is deposited on the substrate placed in the reaction chamber.

In addition, the second storage may temporarily store an inert gas at a predetermined pressure, and the inert gas from the second storage may be rapidly supplied into the reaction chamber in order to remove an unreacted gas and a reaction by-product that remain in the atomic layer deposition apparatus during atomic layer deposition.

The atomic layer deposition apparatus according to the present invention includes the first storage and the second storage, which temporarily store an inert gas or a precursor gas to be supplied into the reaction chamber, in place of mass flow controllers. Consequently, it is possible to reduce time necessary to supply a precursor gas into the reaction chamber. In addition, the vacuum pump evacuates the reaction chamber and, at the same time, supplies an inert gas from the second storage into the reaction chamber in order to discharge an unreacted gas and a reaction by-product that remain in the atomic layer deposition apparatus from the atomic layer deposition apparatus. Consequently, it is possible to increase a discharge speed. Furthermore, the reaction chamber is filled with an inert gas having no impurities from the second storage. Consequently, it is possible to remove a precursor gas and a reaction by-product that remain in the reaction chamber with high removal efficiency, whereby it is possible to manufacture a thin film having high-purity quality.

In addition, the atomic layer deposition apparatus according to the present invention is configured to have a structure in which an inert gas from the gas supply device is supplied into the reaction chamber via the precursor storage. Consequently, it is possible to effectively remove an unreacted gas and a reaction by-product that remain in a precursor gas supply line extending from the outlet of the precursor storage to the chamber inlet of the reaction chamber.

In a concrete example, the vacuum pump may apply vacuum pressure into the reaction chamber to suction an unreacted gas and a reaction by-product that remain in the reaction chamber. Specifically, the vacuum pump may compress the gas in the reaction chamber, and may then discharge the compressed gas.

The inert gas may be at least one selected from a group consisting of nitrogen, argon, and helium.

The reaction chamber may be a batch type, semi-batch type, or single type chamber.

The atomic layer deposition apparatus may further include an automatic controller for controlling operations of the valves.

Each of the valves may be at least one selected from a group consisting of a pneumatic valve, a diaphragm valve, and a solenoid valve.

In accordance with another aspect of the present invention, there is provided an atomic layer deposition method using the atomic layer deposition apparatus with the above-stated construction, the atomic layer deposition method including a first step of placing a substrate in the reaction chamber in a state in which all of the valves of the atomic layer deposition apparatus are OFF, a second step of turning the second valve and the third valve ON to supply a precursor gas from the precursor storage into the first storage and turning the fifth valve ON to supply an inert gas from the gas supply device into the second storage, a third step of turning the second valve and the third valve OFF to close the first storage and turning the fifth valve OFF to close the second storage, a fourth step of turning the first valve ON to supply a precursor gas from the first storage into the reaction chamber such that the precursor gas is deposited on the substrate placed in the reaction chamber, a fifth step of turning the second valve and the fourth valve ON to supply an inert gas from the second storage into the reaction chamber such that an unreacted gas and a reaction by-product that remain in the reaction chamber and the gas conduit connected between the first storage and the reaction chamber are removed, and a sixth step of turning the first valve, the second valve, and the fourth valve OFF.

Specifically, when the second valve and the third valve are turned ON at the second step, the inert gas from the gas supply device is supplied into the precursor storage. As a result, the precursor gas from the precursor storage moves into the first storage.

In the atomic layer deposition method described above, the respective reaction gases are supplied onto the substrate, and one atomic layer is deposited through one deposition process. In order to deposit the atomic layer such that a thin film has a target thickness, therefore, the deposition process is repeatedly performed to control the thickness of the thin film.

In the atomic layer deposition method according to the present invention, therefore, the first step to the sixth step may be sequentially carried out, and then the second step to the sixth step may be repeatedly carried out in a cyclic manner, in order to manufacture the thin film.

In the atomic layer deposition method described above, a factor that determines time during which the precursor gas stays in the reaction chamber may be the size of the reaction chamber or the pressure of the reaction gas in the reaction chamber. For example, at the sixth step, the gas in the reaction chamber may have a pressure of 10 mTorr to 20 Torr, and the precursor gas may stay in the reaction chamber for 100 msec to 10 sec. However, the present invention is not limited thereto.

In accordance with a further aspect of the present invention, there is provided a thin film manufactured using the atomic layer deposition apparatus with the above-stated construction. A precursor gas and a reaction by-product that remain in the reaction chamber are effectively discharged. As a result, the thin film has high-purity quality.

### Advantageous Effects

As is apparent from the above description, the atomic layer deposition apparatus according to the present invention includes the first storage and the second storage, which temporarily store an inert gas or a precursor gas to be supplied into the reaction chamber, in place of mass flow controllers. Consequently, it is possible to reduce time necessary to supply a precursor gas into the reaction chamber and to reduce time necessary to discharge an unreacted gas and a reaction by-product that remain in the atomic layer deposition apparatus from the atomic layer deposition apparatus. In addition, it is possible to remove a precursor gas and a reaction by-product that remain in the reaction chamber and the precursor gas supply line extending from the outlet of the precursor storage to the chamber inlet of the reaction chamber from the atomic layer deposition apparatus with high removal efficiency, whereby it is possible to manufacture a thin film having high-purity quality.

### BRIEF DESCRIPTION OF DRAWINGS

The above and other objects, features and other advantages of the present invention will be more clearly understood from the following detailed description taken in conjunction with the accompanying drawings, in which:

FIG. 1 is a schematic view showing a conventional atomic layer deposition apparatus including mass flow controllers;

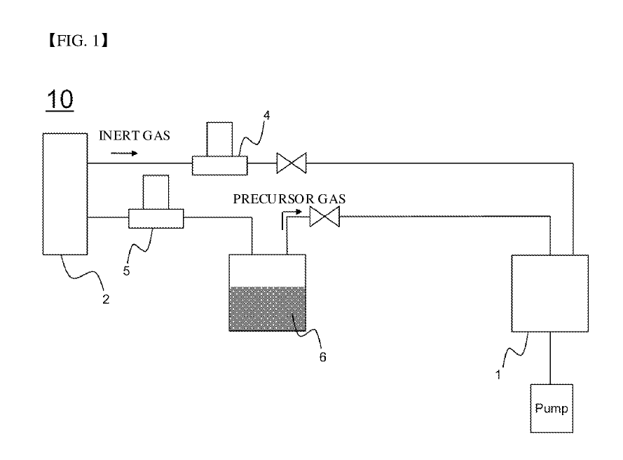

FIG. 2 is a schematic view showing an atomic layer deposition apparatus including a first storage and a second storage according to an embodiment of the present invention;

FIG. 3 is a chart showing ON/OFF operations of valves in an atomic layer deposition method using the atomic layer deposition apparatus of FIG. 2; and

FIG. 4 is a flowchart showing an atomic layer deposition method according to an embodiment of the present invention.

### DETAILED DESCRIPTION OF THE INVENTION

Now, exemplary embodiments of the present invention will be described in detail with reference to the accompanying drawings. It should be noted, however, that the scope of the present invention is not limited by the illustrated embodiments.

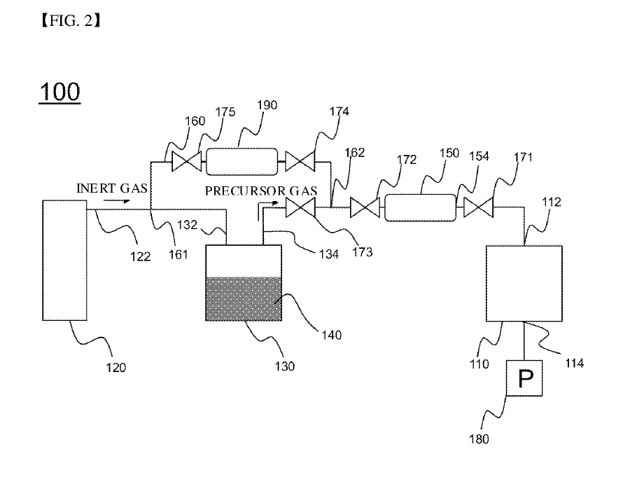

FIG. 2 is a schematic view showing an atomic layer deposition apparatus including a first storage and a second storage according to an embodiment of the present invention.

Referring to FIG. 2, an atomic layer deposition apparatus 100 according to the present invention includes a reaction chamber 110, a gas supply device 120, a precursor storage 130, a first storage 150, a second storage 190, a first valve 171, a second valve 172, a third valve 173, a fourth valve 174, a fifth valve 175, a bypass conduit 160, and a vacuum pump 180, which will be described hereinafter in detail.

The reaction chamber 110 is provided with a chamber inlet 112, through which an inert gas or a precursor gas is introduced into the reaction chamber 110, and a chamber outlet 114, through which gas is discharged from the reaction chamber 110. The reaction chamber 110 is configured to deposit a precursor gas, which is a mixture of an inert gas and a gas-phase precursor, on the surface of a substrate.

The gas supply device 120 is provided with a gas supply pipe 122, along which an inert gas, such as nitrogen, argon, or helium, is supplied to the precursor storage 130. The gas supply device 120 supplies the inert gas to the precursor storage 130 at a predetermined pressure using a power unit disposed in the gas supply device 120.

The precursor storage 130 is provided with an inlet 132, through which the inert gas supplied along the gas supply pipe 122 is introduced into the precursor storage 130, and an outlet 134, through which a precursor gas is discharged from the precursor storage 130. A precursor 140 for generating a precursor gas to be supplied to the reaction chamber 110 is disposed in the precursor storage 130. The precursor 140 is evaporated at the result of being heated to a predetermined temperature. The evaporated precursor 140 is mixed with the inert gas introduced into the precursor storage 130 through the inlet 132 to form a precursor gas (not shown).

The first storage 150 is connected to the chamber inlet 112. The first storage 150 temporarily stores a precursor gas to be supplied into the reaction chamber 110.

The second storage 190 is located on the bypass conduit 160. The second storage 190 temporarily stores an inert gas to be supplied into the reaction chamber 110.

The first valve 171 is located at an outlet 154 of the first storage 150. The first valve 171 controls the supply of an inert gas or a precursor gas from the first storage 150 into the reaction chamber 110.

The second valve 172 is located at an inlet of the first storage 150. The second valve 172 controls the supply of an inert gas or a precursor gas into the first storage 150.

The third valve 173 is connected to the outlet 134 of the precursor storage 130. The third valve 173 is connected to the second valve 172 via a gas conduit such that a precursor gas is fed to the second valve 172.

One end 161 of the bypass conduit 160 is connected to the gas supply pipe 122, and the other end 162 of the bypass conduit 160 is connected to the gas conduit between the second valve 172 and the third valve 173.

The fourth valve 174 is located at an outlet of the second storage 190. The fourth valve 174 controls the supply of an inert gas from the second storage 190 to the gas conduit between the second valve 172 and the third valve 173.

The fifth valve 175 is located at an inlet of the second storage 190. The fifth valve 175 controls the supply of an inert gas from the gas supply pipe 122 into the second storage 190.

The vacuum pump 180 is connected to the chamber outlet 114 of the reaction chamber 110. The vacuum pump 180 discharges an unreacted gas and a reaction by-product that remain in the reaction chamber 110 and a precursor gas supply line extending from the outlet 134 of the precursor storage 130 to the chamber inlet 112 of the reaction chamber 110 from the atomic layer deposition apparatus 100.

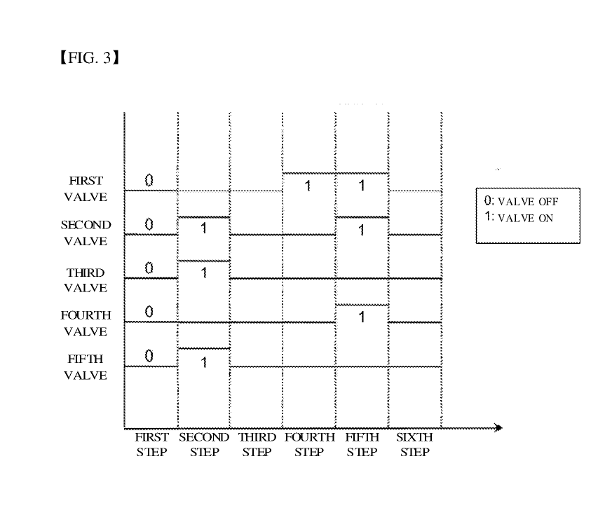

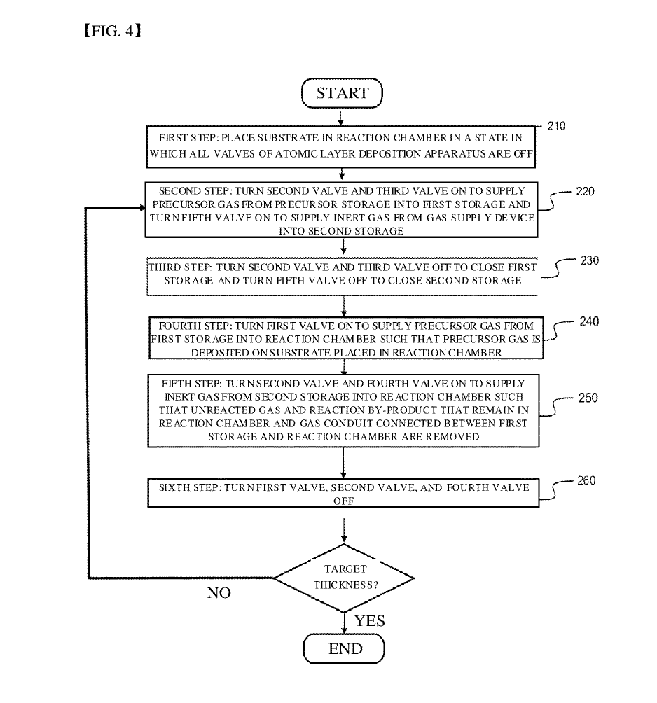

FIG. 3 is a chart showing ON/OFF operations of the valves in an atomic layer deposition method using the atomic layer deposition apparatus 100 of FIG. 2, and FIG. 4 is a flowchart showing an atomic layer deposition method according to an embodiment of the present invention.

Referring to FIGS. 3 and 4 together with FIG. 2, the atomic layer deposition method using the atomic layer deposition apparatus 100 according to the present invention includes a step of placing a substrate (not shown) in the reaction chamber 110 in a state in which all of the valves 171, 172, 173, 174, and 175 of the atomic layer deposition apparatus 100 are OFF (a first step (210)), a step of turning the second valve 172 and the third valve 173 ON to supply a precursor gas from the precursor storage 130 into the first storage 150 and turning the fifth valve 175 ON to supply an inert gas from the gas supply device 120 into the second storage 190 (a second step (220)), a step of turning the second valve 172 and the third valve 173 OFF to close the first storage 150 and turning the fifth valve 175 OFF to close the second storage 190 (a third step (230)), a step of turning the first valve 171 ON to supply a precursor gas from the first storage 150 into the reaction chamber 110 such that the precursor gas is deposited on the substrate placed in the reaction chamber 110 (a fourth step (240)), a step of turning the second valve 172 and the fourth valve 174 ON to supply an inert gas from the second storage 190 into the reaction chamber 110 such that an unreacted gas and a reaction by-product that remain in the reaction chamber 110 and the gas conduit connected between the first storage 150 and the reaction chamber 110 are removed (a fifth step (250)), and a step of turning the first valve 171, the second valve 172, and the fourth valve 174 OFF (a sixth step (260)).

In the atomic layer deposition method described above, one atomic layer is deposited through one deposition process. In order to deposit the atomic layer such that a thin film has a target thickness, therefore, the first step (210) to the sixth step (260) may be sequentially carried out. In a case in which the thin film does not have the target thickness, the second step (220) to the sixth step (260) may be repeatedly carried out in a cyclic manner

The atomic layer deposition apparatus 100 according to the present invention includes the first storage 150 and the second storage 190. Consequently, it is possible to reduce time necessary to supply a precursor gas into the reaction chamber 110 and to reduce time necessary to discharge an unreacted gas and a reaction by-product that remain in the atomic layer deposition apparatus 100 from the atomic layer deposition apparatus 100. In addition, it is possible to discharge a precursor gas and a reaction by-product that remain in the reaction chamber 110 and the precursor gas supply line extending from the outlet 134 of the precursor storage 130 to the chamber inlet 112 of the reaction chamber 110 from the atomic layer deposition apparatus 100 with high discharge efficiency, whereby it is possible to manufacture a thin film having high-purity quality.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

1. An atomic layer deposition apparatus comprising:
a reaction chamber provided with a chamber inlet, through which an inert gas or a precursor gas, which is a mixture of the inert gas and a gas-phase precursor, is introduced into the reaction chamber, and a chamber outlet, through which gas is discharged from the reaction chamber;
a gas supply device provided with a gas supply pipe, along which an inert gas is supplied;
a precursor storage having a precursor for generating a precursor gas to be supplied to the reaction chamber received therein, the precursor storage being provided with an inlet, through which the inert gas supplied along the gas supply pipe is introduced into the precursor storage, and an outlet, through which the precursor gas is discharged from the precursor storage;
a first storage connected to the chamber inlet for temporarily storing an inert gas or a precursor gas to be supplied into the reaction chamber;
a first valve located at an outlet of the first storage for controlling a supply of the inert gas or the precursor gas from the first storage into the reaction chamber;
a second valve located at an inlet of the first storage for controlling a supply of the inert gas or the precursor gas into the first storage;
a third valve connected to the outlet of the precursor storage and to the second valve via a gas conduit;
a bypass conduit having one end connected to the gas supply pipe and the other end connected to the gas conduit between the second valve and the third valve;
a second storage located on the bypass conduit for temporarily storing an inert gas;
a fourth valve located at an outlet of the second storage for controlling a supply of an inert gas from the second storage to the gas conduit between the second valve and the third valve;
a fifth valve located at an inlet of the second storage for controlling a supply of an inert gas from the gas supply pipe into the second storage; and
a vacuum pump connected to the chamber outlet of the reaction chamber for discharging an unreacted gas and a reaction by-product that remain in the reaction chamber and the gas conduit from the atomic layer deposition apparatus.

2. The atomic layer deposition apparatus according to claim 1, wherein the vacuum pump compresses the gas in the reaction chamber and discharges the compressed gas.

3. The atomic layer deposition apparatus according to claim 1, wherein the inert gas is at least one selected from a group consisting of nitrogen, argon, and helium.

4. The atomic layer deposition apparatus according to claim 1, wherein the reaction chamber is a batch type, semi-batch type, or single type chamber.

5. The atomic layer deposition apparatus according to claim 1, further comprising an automatic controller for controlling operations of the valves.

6. The atomic layer deposition apparatus according to claim 1, wherein each of the valves is at least one selected from a group consisting of a pneumatic valve, a diaphragm valve, and a solenoid valve.

7. An atomic layer deposition method using an atomic layer deposition apparatus according to claim 1, the atomic layer deposition method comprising:
a first step of placing a substrate in the reaction chamber in a state in which all of the valves of the atomic layer deposition apparatus are OFF;
a second step of turning the second valve and the third valve ON to supply a precursor gas from the precursor storage into the first storage and turning the fifth valve ON to supply an inert gas from the gas supply device into the second storage;
a third step of turning the second valve and the third valve OFF to close the first storage and turning the fifth valve OFF to close the second storage;
a fourth step of turning the first valve ON to supply a precursor gas from the first storage into the reaction chamber such that the precursor gas is deposited on the substrate placed in the reaction chamber;
a fifth step of turning the second valve and the fourth valve ON to supply an inert gas from the second storage into the reaction chamber such that an unreacted gas and a reaction by-product that remain in the reaction chamber and the gas conduit connected between the first storage and the reaction chamber are removed; and
a sixth step of turning the first valve, the second valve, and the fourth valve OFF.

8. The atomic layer deposition method according to claim 7, wherein the first step to the sixth step are sequentially carried out, and then the second step to the sixth step are repeatedly carried out in a cyclic manner.

9. The atomic layer deposition method according to claim 7, wherein, at the sixth step, the reaction gas in the reaction chamber has a pressure of 10 mTorr to 20 Torr.

10. The atomic layer deposition method according to claim 7, wherein, at the sixth step, the precursor gas stays in the reaction chamber for 100 msec to 10 sec.

11. A thin film manufactured using an atomic layer deposition apparatus according to claim 1.
